(19) United States
(12) Patent Application Publication
(10) Pub. No.: US 2026/0251707 A1
(43) Pub. Date: Aug. 27, 2026

(54) CONCURRENT TESTING DEVICE AND METHOD FOR INTEGRATED CIRCUIT

(71) Applicant: MACROTEST SEMICONDUCTOR TECHNOLOGY CO., LTD, Nanjing (CN)

(72) Inventors: Guoliang MAO, Nanjing (CN); Yanlin WU, Nanjing (CN); Zhijie BAO, Nanjing (CN)

(21) Appl. No.: 18/714,083

(22) PCT Filed: Mar. 15, 2023
(86) PCT No.: PCT/CN2023/081508

§ 371 Date: May 28, 2024

(30) Foreign Application Priority Data
May 18, 2022 (CN) 202210536671.4

(51) Int. Cl. G01R 31/317; G01R 31/3181

(52) U.S. Cl. CPC G01R 31/31727; G01R 31/31726; G01R 31/31813

(57) ABSTRACT

The present disclosure discloses a concurrent testing device and method for an integrated circuit. The device includes a test processor (TP), a Parameter Pattern compiler (PPC), a channel parameter test controller PTC, and an instruments control bus (ICB). A new control bus is established between the test processor and an analog test channel, and compilation and interpretive execution of the analog test channel between the test processor and the analog test channel are achieved, thereby unifying analog signal testing and digital signal testing into the test processor. The present invention not only improves the testing efficiency, but also improves the testing coverage.

### TECHNICAL FIELD

The present disclosure relates to a concurrent testing device and method for an integrated circuit, and belongs to the field of auto testing of integrated circuits.

### BACKGROUND

With the maturity of a multi-chip packaging technology for integrated circuits and the integration of more mixed digital and analog signals on a single chip, in auto test equipment (ATE) for integrated circuits, more challenges have been posed on how to more efficiently complete mixed testing of digital and analog signals in synchronous concurrent testing or asynchronous concurrent testing between multiple test sites. For example, during testing of a system on chip (SOC), it is necessary to continuously send Trimming data to the chip through a digital channel and a Serial Peripheral Interface (SPI) interface, and a Ref voltage output is then tested through an analog source to look for an optimal trimming value. Due to an increasing large scale of the SOC and more and more integrated analog signals such as a reference voltage, a proportion of time spent on such scan test to overall test time constantly increases.

A traditional testing solution is to complete digital signal testing by a test processor and complete analog signal testing by a personal computer (PC). The digital signal testing and the analog signal testing are switched to be performed between the two processors. For example, the test processor sends SPI data and changes an output of a Ref voltage output of a chip, and then the PC measures a voltage value of the Ref signal, following this cycle. This method has the advantages of low cost and flexible programming, but there are several issues:
1. Testing is switched to be performed between the two processors, so that it spends much time in switching, and the testing efficiency is low.
2. For testing with multiple test sites, since the PC can only read testing data serially through a Peripheral Component Interface Express (PCIE) bus, the PC can only test analog signals of the various test sites in series, causing low testing efficiency.
3. For a situation where the various test sites cannot be synchronized, for example, after succeeding in the digital signal testing, the chip outputs an analog pulse signal after a period of time. However, the generation times of rising edges of the analog pulse signals at the various test sites are inconsistent, so that the various test sites need to independently complete matching testing of the analog signals concurrently. Meanwhile, the analog signal testing needs to be accurately synchronized with the digital signal testing. This situation is suitable for traditional testing methods because the analog signal testing needs to be switched to be performed in the PC, and the PC can only perform serial testing and cannot be accurately synchronized with tested signals. As a result, the various test sites cannot complete testing concurrently.

### SUMMARY

Objectives of this invention: To overcome the shortcomings in the prior art, the present disclosure provides a concurrent testing device and method for an integrated circuit. The key of the present disclosure is to unify analog signal testing and digital signal testing into a test processor. A digital signal is generated by a digital signal generation board, and an analog signal is generated by an independent analog signal generation board, such as an analog power supply board and an arbitrary signal generator board. Both the analog and digital boards are controlled directly by a personal computer (PC) through a system backplane bus. To integrate analog signal testing into a test processor, a new control bus needs to be established between the test processor and an analog test channel. Furthermore, the compilation and interpretive execution of the analog test channel between the test processor and the analog test channel are achieved.

Technical solutions: In order to achieve the above objectives, the present disclosure adopts the following technical solutions:

A concurrent testing device for an integrated circuit includes a test processor (TP), a Parameter Pattern compiler (PPC), a parameter test controller (PTC), and an instruments control bus (ICB), wherein
the TP includes a timing generator (TG), a pattern generator, a signal processing unit control instruction generator, a pattern memory, a memory control, and an instrument control bus message generator (ICMG); the memory control is respectively connected to the TG, the pattern generator, the signal processing unit control instruction generator, and the ICMG, and the pattern generator is respectively connected to the TG and the signal processing unit control instruction generator;
a pattern generator file processed by the TP includes two or more instrument control opcode combination vectors; each instrument control opcode combination vector is composed of a pattern generator control instruction, a timing set, a digital channel list, and an analog device pin list; the analog device pin list is composed of instrument control opcodes;
the PPC converts the instrument control opcodes into instruments control messages (ICM) according to a conversion table for instrument control opcodes and ICMs; and
the PPC is connected to the PTC through the ICB.

Preferably, each unique instrument control opcode combination vector is referred to as an instrument control opcode group.

Preferably, two or more instrument control opcode groups form an instrument control opcode table.

Preferably, each unique instrument control opcode combination vector is assigned with an instrument control opcode value.

A concurrent testing method for an integrated circuit includes the following steps:
Step 1, sending an ICM by a TP through an ICMG 5, wherein the ICM is transmitted through an ICB and enters an instruments control bus receiver controller (ICBRC) of each test channel;
Step 2, converting, by the ICBRC, the ICM into an instruments control code (ICC) of the channel; and
Step 3, parsing the ICC via the PTC to complete final control of an analog channel.

Preferably, the same ICM is mapped into different ICCs through the ICBRCs of various different channels to correspond to instrument control opcodes (ICOs) of the respective channels.

Preferably, the ICBRC selectively receives the ICM from a specified test processor, thereby allowing a plurality of test processors to concurrently control a group of analog test channels specified by the respective test processors.

Compared with the prior art, the present disclosure has the following technical effects:

The present disclosure unifies digital signal testing and analog signal testing into the control of the test processor, thereby avoiding various problems of traditional testing and achieving the following advantages:
1. As ATE may have a plurality of test processors (each test site can be assigned with one test processor), and each test processor can work asynchronously and concurrently, asynchronous and concurrent mixed testing of digital and analog signals can be well completed.
2. As both the digital signal testing and the analog signal testing are directly completed by the test processors, the timing of the digital signal testing and the timing of the analog signal testing can be accurately synchronized, so that complex mixed digital and analog signal testing can be accurately completed.
3. By unifying the programming of the digital signal testing and the programming of the analog signal testing in one pattern file, the difficulty of test programming is lowered, and the efficiency of developing and debugging mixed signal test programs is improved.

### BRIEF DESCRIPTION OF THE DRAWINGS

FIG. 1 is a schematic diagram of an internal structure of a test processor.

FIG. 2 is a schematic diagram of a traditional pattern file.

FIG. 3 is a schematic diagram of a pattern file according to an embodiment of the present disclosure.

FIG. 4 is a conversion table for ICOs and ICMs.

FIG. 5 is a schematic diagram of control of a multi-channel concurrent testing device, specifically a process of how to send an ICM from a test processor to an analog test channel.

FIG. 6 is a schematic diagram of mixed concurrent digital and analog testing of multiple test sites.

### DETAILED DESCRIPTION OF THE EMBODIMENTS

Based on the accompanying drawings and specific embodiments, the present disclosure will be further elaborated. It should be understood that these examples are only used to illustrate the present disclosure and not to limit the scope of the present disclosure. After reading the present disclosure, modifications to various equivalent forms of the present disclosure by those skilled in the art shall all fall within the scope defined by the claims attached to the present disclosure.

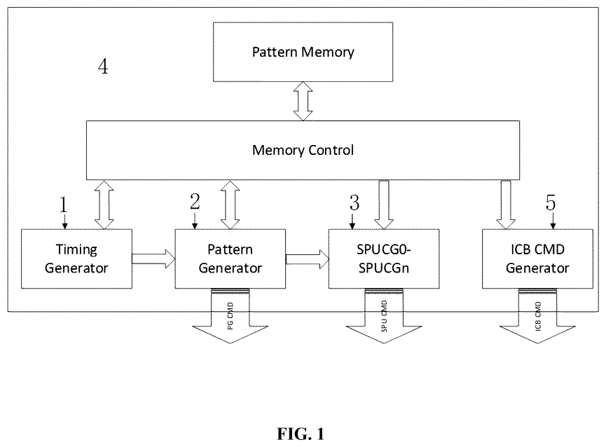

A concurrent testing device for an integrated circuit, as shown in FIG. 1, includes a Test Processor 4 (TP), a Parameter Pattern Compiler (PPC), a Parameter Test Controller (PTC), and an Instruments Control Bus (ICB).

The test processor 4 includes a timing generator (TG) 1, a pattern generator 2, a signal processor unit command generator 3, a pattern memory, a memory control, and an instruments control message generator (ICMG) 5. The memory control is respectively connected to the TG 1, the pattern generator 2, the signal processor unit command generator 3, and the instruments control message generator 5, and the pattern generator 2 is respectively connected to the TG 1 and the signal processor unit command generator 3.

The TG 1 is configured to generate precise timing signals (including a cycle, a time edge, and the like) required by each cycle according to a timing requirement specified by a pattern file.

The pattern generator 2 is configured to generate a control timing (including jump, loop, and the like) required by pattern testing according to a command requirement of a pattern file.

The signal processor unit command generator (SPUCG) 3 is configured to generate command signals for synchronous control of digital test channel subsystems according to a pattern file control data requirement.

The test processor 4 is TP for short. The TG1, the pattern generator 2, and the signal processor unit command generator 3 access the pattern memory through the memory control to obtain commands and data. The TG1 is responsible for generating corresponding cycle and clock edge information of a current cycle and providing the corresponding cycle and clock edge information to other modules. The pattern generator 2 is responsible for executing command requirements in a pattern file to achieve jump and loop, and controlling an access of the memory control to an address of the pattern memory. The signal processor unit command generator 3 sends a control command of a test subsystem to corresponding subsystems under the control of the pattern generator 2, which achieves synchronous control on the subsystems. In addition, according to the architecture diagram, it can be seen that the TP4 is a typical processor with a Von Neumann structure, but a command set uses a command set special for ATE, which is specifically configured to process signals rather than data.

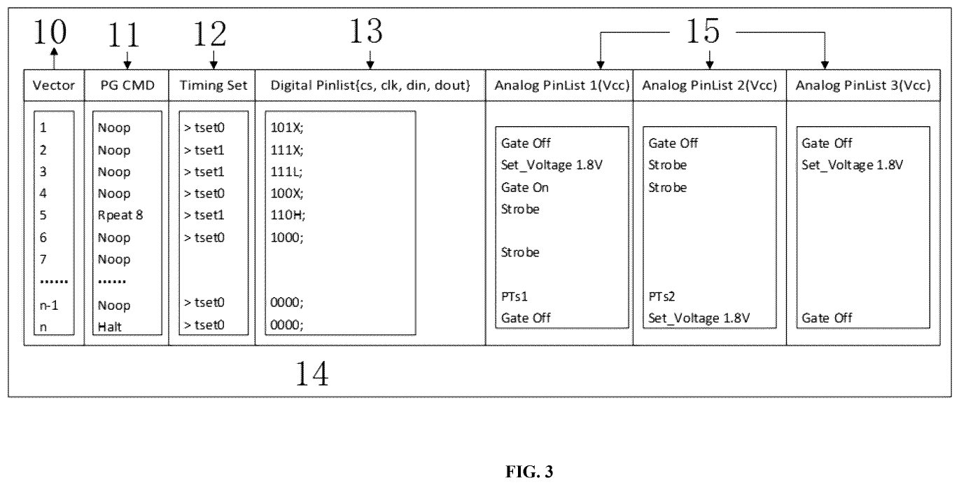

The instruments control message generator (ICMG) 5 is configured to convert instrument control opcodes (ICO, specifically refer to FIG. 3) into instruments control messages (ICM). The ICB transmits the messages to the various PTCs, so that the test processor completes testing control of various non-digital channels.

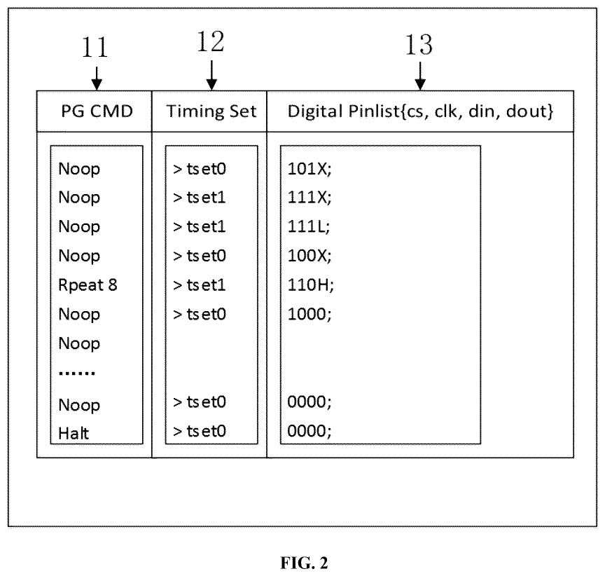

As shown in FIG. 2, a pattern file processed by a traditional test processor is shown. The pattern file processed by the traditional test processor is composed of a pattern generator command 11, a timing set 12, and a digital channel list 13, thus providing all the information required by the pattern test generator.

The pattern generator command 11 generates a control timing required by pattern testing, including: jump, loop, halt, and the like.

The timing set 12 defines precise timing information (including cycle, time edge, and the like) required for the pattern generator to generate each cycle

The digital channel list 13 describes working states of various digital channels under different timing conditions in each cycle. According to the requirements, these channels can be set to different modes. For example, input/output (I/O) can be used as either a driver pin or a receiver pin. Valid data of the driver pin includes 0 and 1, and valid data of the receiver pin includes L, H, and X.

According to FIG. 3, it can be seen that all controls are aimed at digital test channels, which can accurately describe a test timing of each digital test channel.

According to the embodiments of the present disclosure, control command content of an analog channel pin is added on the basis of an original pattern. As shown in FIG. 3, a pattern generator file processed by the TP4 in this embodiment includes two or more instrument control opcode combination vectors; each instrument control opcode combination vector is composed of a pattern generator command 11, a timing set 12, a digital channel list 13, and an analog device pin list 15; and the analog device pin list 15 is composed of instrument control opcodes. All information required by the test processor is provided. Through these commands, it is possible to add control on analog test channels on the basis of pure control on digital test channels. Thus, digital signal testing and analog signal testing can be described in one pattern file simultaneously.

As shown in FIGS. 3, 10 represents a vector in each row of the pattern file. A vector index listed here is for convenience in subsequent introductions and is not included in an actual pattern file. The pattern generator command 11, the timing sets 12, and the digital channel list 13 are the same as the content of a traditional pattern file.

The analog device pin list 15 may contain a plurality of analog device channel controls (including three controls here), which are ICOs. These commands can define a state of an analog device, such as setting a voltage value (Set_Voltage 1.8V), setting an output of an analog channel to be in a Gate-Off state, and acquiring a device under test (DUT) strobe.

The pattern generator file processed by the TP 4 in this embodiment can control both digital test channels and analog channels and can accurately describe test timings of each digital test channel and each analog test channel.

A next problem to be solved is how a test processor can simultaneously send a group of ICOs to CPTCs of a plurality of non-digital test channels to complete synchronous control, thus enabling the various channels to perform different operations.

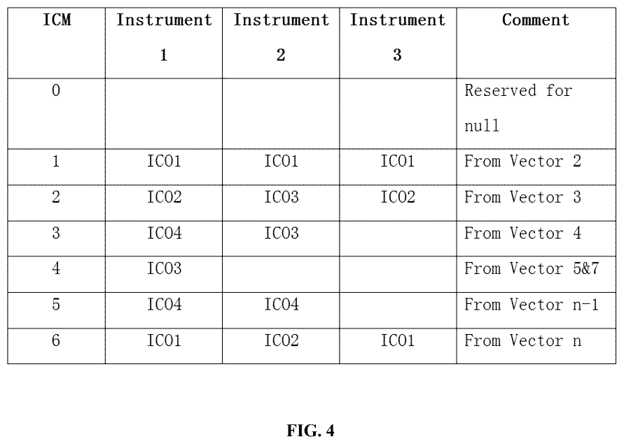

Firstly, a control command group needs to be converted into an ICM. As shown in FIG. 4, how a compiler converts an ICO into an ICM is illustrated.

Each vector of a new pattern file may include a plurality of analog test channel command lists. A plurality of ICOs in each row of vector represent an instrument control opcode combination. Each unique control command combination is referred to as an instrument control opcodes group (ICOG) (refer to FIG. 3), and multiple unique ICOGs form an ICM Table. Each row of ICOG is assigned with an ICM value.

As shown in FIG. 4, a Gate_Off command in FIG. 3 may be compiled as ICO1; Set_Voltage 1.8V may be compiled as ICO 2; Strobe may be compiled as ICO 3; and Gate On may be compiled as ICO4. There are six unique ICOGs in FIG. 3 (Vector 5 and Vector 7 are the same, so they can only be counted as one). After compilation, six different ICMs will be generated.

The PPC converts the instrument control opcodes into ICM according to a conversion table for instrument control opcodes and ICMs. The PPC is connected to the PTC through the ICB.

The PPC compiles an entire pattern test program into commands that can be executed by a device. The pattern test program may include control commands related to instruments and meters (there are many other control commands) for compilation according to test requirements. These compiled commands may be transmitted to the ICMG5 for parsing, and commands that can be recognized by instrument modules and meter modules are then generated. These commands may be sent to the ICB, and those instruments that can recognize these commands are managed through an instruments control bus receiver controller (ICBRC).

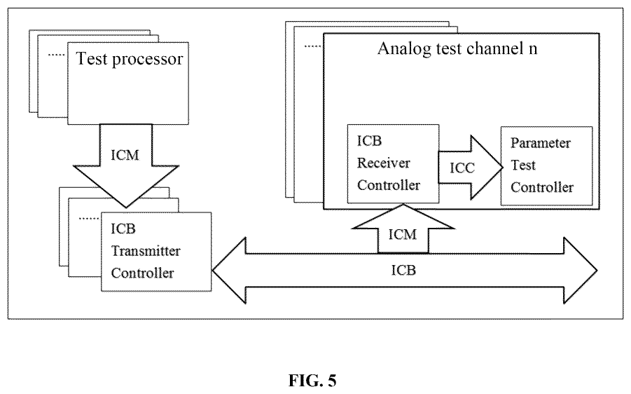

A concurrent testing method for an integrated circuit, as shown in FIG. 5, includes the following steps:
Step 1, sending an ICM by a TP4 through an ICMG 5, wherein the ICM is transmitted through an ICB and enters an instruments control bus receiver controller (ICBRC) of each test channel;
Step 2, converting, by the ICBRC, the ICM into an instruments control code (ICC) of the channel; and
Step 3, parsing the ICC via the PTC to complete final control of an analog channel.

The same ICM is mapped into different ICCs through the ICBRCs of various different channels to correspond to instrument control opcodes (ICOs) of the respective channels. Thus, a plurality of analog test channels can be synchronously controlled through one test processor to simultaneously complete different tests.

Meanwhile, the ICBRC selectively receives the ICM from a specified test processor, thereby allowing a plurality of test processors to concurrently control a group of analog test channels specified by the respective test processors. If one test processor is assigned to each test site, concurrent multi-clock domain testing of a plurality of test sites can be achieved.

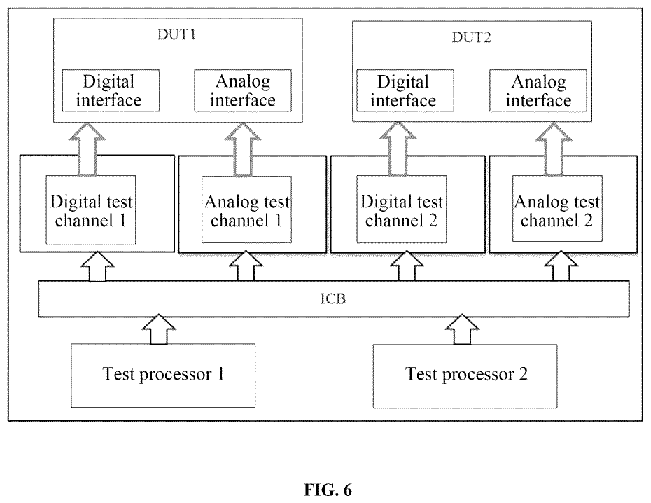

As shown in FIG. 6, two devices under test are shown. The present disclosure is also applicable to more devices under test. According to FIG. 6, it can be seen that each Device Under Test (DUT) is assigned with a group of digital test channels and a group of analog test channels. Each DUT is controlled by an independent test processor. When two test processors work in different clock domains, the two DUTs can work in a concurrent testing state. From FIG. 6, it can be seen that a PC will not participate in controlling the digital test channels and the analog test channels in a testing process. Multi-clock domain testing is also applicable to a situation in a single DUT.

The present disclosure can unify digital testing and analog testing in the same pattern file, so as to simplify the development of test programs. Both the digital test channels and the analog test channels can be synchronously and concurrently controlled, without direct switching between a test processor and a PC processor, thus improving the testing efficiency and reducing the testing costs. Precise synchronization between the analog testing channels and the digital testing channels can be achieved, thereby achieving more complex integrated circuit parameter testing and improving the testing coverage.

The foregoing descriptions are preferable implementations of the present disclosure only. It is noted that a person of ordinary skill in the art may make some improvements and modifications without departing from the principle of the present disclosure and the improvements and modifications shall fall within the protection scope of the present disclosure.

What is claimed is:

1. A concurrent testing device for an integrated circuit, comprising a test processor (TP) (4), a Parameter Pattern compiler (PPC), a parameter test controller (PTC), and an instruments control bus (ICB), wherein
the TP (4) comprises a timing generator (TG) (1), a pattern generator (2), a signal processor unit command generator (3), a pattern memory, a memory control, and an instruments control message generator (ICMG) (5); the memory control is respectively connected to the TG (1), the pattern generator (2), the signal processor unit command generator (3), and the ICMG (5), and the pattern generator (2) is respectively connected to the TG (1) and the signal processor unit command generator (3);
the TG (1), the pattern generator (2), and the signal processor unit command generator (3) access the pattern memory through the memory control to obtain commands and data;
the TG (1) is responsible for generating corresponding cycle and clock edge information of a current cycle;
the pattern generator (2) is responsible for executing command requirements in a pattern file to achieve jump and loop, and controlling an access of the memory control to an address of the pattern memory;
the signal processor unit command generator (3) generates a command signal for synchronously controlling digital test channel subsystems under the control of the pattern generator (2), achieving synchronous control on the subsystems;
a pattern generator file processed by the TP (4) comprises two or more instrument control opcode combination vectors; each instrument control opcode combination vector is composed of a pattern generator command (11), a timing set (12), a digital channel list (13), and an analog device pin list (15);
the pattern generator command (11) is used for generating a control timing required for pattern testing;
the timing set (12) is used for defining precise timing information required for the pattern generator to generate each cycle;
the digital channel list (13) is used for describing working states of various digital channels under different timing conditions in each cycle;
the analog device pin list (15) is composed of instrument control opcodes;
the PPC converts the instrument control opcodes into instruments control messages (ICM) according to a conversion table for instrument control opcodes and ICMs; and
the PPC is connected to the PTC through the ICB.

2. The concurrent testing device for the integrated circuit according to claim 1, wherein each unique instrument control opcode combination vector is referred to as an instrument control opcode group.

3. The concurrent testing device for the integrated circuit according to claim 2, wherein two or more instrument control opcode groups form an instrument control opcode table.

4. The concurrent testing device for the integrated circuit according to claim 3, wherein each unique instrument control opcode combination vector is assigned with an instrument control opcode value.

5. A testing method of the concurrent testing device for the integrated circuit according to claim 1, comprising the following steps:
Step 1, sending an ICM by the TP (4) through the ICMG (5), wherein the ICM is transmitted through the ICB and enters an instruments control bus receiver controller (ICBRC) of each test channel;
Step 2, converting, by the ICBRC, the ICM into an instruments control code (ICC) of the channel; and
Step 3, parsing the ICC via the PTC to complete final control of an analog channel.

6. The testing method according to claim 5, wherein the same ICM is mapped into different ICCs through the ICBRCs of various different channels to correspond to instrument control opcodes (ICOs) of the respective channels.

7. The testing method according to claim 6, wherein the ICBRC selectively receives the ICM from a specified test processor, thereby allowing a plurality of test processors to concurrently control a group of analog test channels specified by the respective test processors.
